(19) United States
(12) Patent Application Publication
(10) Pub. No.: US 2017/0019055 A1
(43) Pub. Date: Jan. 19, 2017

(54) BALLOON EQUIPPED WITH A CONCENTRATED SOLAR GENERATOR AND EMPLOYING AN OPTIMISED ARRANGEMENT OF SOLAR CELLS TO POWER SAID BALLOON IN FLIGHT

(71) Applicant: THALES, Courbevoie (FR)

(72) Inventors: Bertrand BOULANGER, CANNES LA BOCCA (FR); Jean-Pierre PROST, CANNES LA BOCCA (FR); Jean-Philippe CHESSEL, CANNES LA BOCCA (FR); Thierry DARGENT, CANNES LA BOCCA (FR)

(21) Appl. No.: 15/209,691

(22) Filed: Jul. 13, 2016

(30) Foreign Application Priority Data
Jul. 15, 2015 (FR) 1501486

(51) Int. Cl. H02S 10/40; B64B 1/40; H01L 31/05; H01L 31/046; H01L 31/0232

(52) U.S. Cl. CPC H02S 10/40; H01L 31/046; H01L 31/02327; H01L 31/0516; B64B 1/40

(57) ABSTRACT

A balloon comprises an envelope containing a lifting gas and a concentrated solar radiation solar generator. The solar generator includes a reflector, one or two arrays of photovoltaic solar cells forming a first active face directed towards the reflector and a second active face directed towards the exterior of the envelope of the balloon. The reflector, the first active face and the second active face of the array of photovoltaic cells are configured so as to ensure the first active face and the second active face of the array both generate electrical power provided that the rollwise solar misalignment of the reflector is smaller than or equal to 10 degrees in absolute value.

### CROSS-REFERENCE TO RELATED APPLICATION

This application claims priority to foreign French patent application No. FR 1501486, filed on Jul. 15, 2015, the disclosures of which are incorporated by reference in their entirety.

### FIELD OF THE INVENTION

The present invention relates to a balloon equipped with a concentrated solar generator and using an optimised arrangement of solar cells to power said balloon in flight.

The invention in particular relates to a high-altitude balloon intended to cruise in the stratosphere and bearing, fastened below, a gondola carrying one or more payloads on board.

### BACKGROUND

Generally, balloons have great potential applicability not only because of their low cost relative to that of satellites but also because of the altitudes, especially those of the stratosphere extending between 12 and 45 km, at which said balloons cruise and which they may usefully exploit.

Whereas the stratosphere is inaccessible to satellites and passed through too rapidly by rocket probes, balloons, or aerostats to use the scientific terminology, may cruise for a long time in this “middle” layer of the atmosphere, and are particularly promising vis-à-vis the requirements of a certain number of applications, in particular in the field of telecommunications.

Conventionally, high-altitude balloons must meet two requirements:

on the one hand they must provide satisfactory lift, and hence the envelope of the balloon must have an adequate volume; and

on the other hand thrust must be provided in order to allow the balloon to be piloted and made to follow a desired path, this requiring the availability of a sufficient source of power.

Generally and conventionally, for a dirigible high-altitude balloon to be able to maintain its station autonomously for several months, it is necessary for it to produce its own power using photovoltaic cells. Under stratospheric wind conditions (winds having speeds higher than 10 m/s are typical) and for a permanent and continuous mission, electrical power produced during the day is stored on board in order to be used at night. Daytime electricity generation rapidly reaches a few tens of kilowatts and requires a large area of photovoltaic cells, which significantly and detrimentally impacts the weight budget of the balloon.

In order to decrease the number of photovoltaic cells required to generate enough electrical power for a given mission, and thus to decrease the overall weight of the balloon, patent application FR 2 982 840 describes a balloon equipped with a concentrated solar generator. The balloon uses photovoltaic means having an active face intended to receive solar rays and includes an envelope. The envelope comprises at least one first zone that is transparent to the solar rays, a second zone that reflects said solar rays, and a third zone comprising said photovoltaic means. The second and third zones are positioned and interact so as to redirect the solar rays towards said third zone.

Such a balloon equipped with a concentrated solar generator is subject at least locally to a temperature increase, this creating a risk of damage with respect to the envelope and/or lifting gas that the envelope contains, in particular when the lifting gas is inflammable.

In addition, the use of a concentrated solar generator means that the concentrator or reflecting means must be continously controlled to align it or them towards the sun. In the case of solar misalignment, for example dictated by particular mission requirements (pointing of antenna(e) or sensors) or meteorological conditions or limits on the tracking of the sun itself, it is recommendable to mitigate the rapid decrease in the electrical power delivered by the concentrated solar generator when the angle of incidence of the solar radiation varies with respect to the balloon.

Furthermore, the increase in the temperature of the solar or photovoltaic cells, which increase is induced by the concentration of the solar radiation, degrades the efficiency of the solar cells, in terms of conversion of solar energy into electrical power.

A first technical problem is to decrease the temperature of the concentrating system in order to decrease the risks with respect to the envelope and the lifting gas contained in the envelope.

A second technical problem is furthermore to mitigate the rapid drop in the electrical power delivered by the solar panel as a function of the angle of incidence of the solar radiation in case of solar misalignment.

A third technical problem is furthermore to decrease the temperature of the solar cells in order to make them operate with a better efficiency.

### SUMMARY OF THE INVENTION

For this purpose, the subject of the invention is a balloon equipped with a concentrated solar generator comprising an envelope containing a lifting gas and a concentrated solar radiation solar generator, the solar generator including:

a reflector of solar rays, which reflector is placed inside the envelope in a first zone of the envelope;

a second zone of the envelope, which is transparent to the solar rays, in order to let the solar rays pass to the reflector; and

a first array of photovoltaic cells, which array is placed in a third zone of the envelope, having a first active face directed towards the reflector;

the first array of photovoltaic cells and the reflector being configured so that the reflector concentrates the solar rays on the first active face of the first array of photovoltaic cells when the reflector is placed in a solar alignment position;

said balloon being characterised in that

the solar generator furthermore includes a second array of photovoltaic cells, which array is placed in a fourth zone of the envelope or in the third zone of the envelope, and having a second active face directed towards the exterior of the envelope; or

the solar generator includes a single first array the solar cells of which are two-sided solar cells and the first array includes a second active face directed towards the exterior of the envelope; and

the reflector, the single first array of two-sided photovoltaic cells or the first and second arrays of photovoltaic cells are configured so as to ensure the first active face and the second active face both generate electrical power provided that the rollwise solar misalignment of the reflector is smaller than or equal to 10 degrees in absolute value.

According to particular embodiments, the balloon equipped with a concentrated solar generator comprises one or more of the following features:

the reflector, the single first array of two-sided photovoltaic cells or the first and second arrays of photovoltaic cells are configured so as to keep the second active face illuminated provided that the rollwise solar misalignment of the second active face is smaller than or equal to 80 degrees;

the first and second arrays of photovoltaic cells are separate and placed in different third and fourth zones, respectively;

the first and second arrays of photovoltaic cells are separate and each include single-sided photovoltaic cells; and the first and second arrays are placed on and outside of the envelope in the same zone; and the first and second arrays are mutually superposed, the second array being placed outermost from the envelope and the active faces of the photovoltaic cells of the first and second arrays being oriented in opposite directions;

the first array and the second array are mechanically decoupled from the envelope in terms of deformations of the envelope and/or thermally from the envelope and from the lifting gas that the envelope contains;

the first array of photovoltaic cells is an array of two-sided photovoltaic cells, which array is located above the third zone of the envelope, each two-sided cell having a first face associated with a first electrical bias and a second face associated with a second electrical bias;

the technology used to manufacture the two-sided cells is a technology chosen from the group consisting of the PERT (passivated emitter rear totally diffused) silicon technology, the silicon heterojunction (HTJ) technology and the IBC (interdigitated back contact) silicon technology;

the technology used to manufacture and connect the two-sided cells is a two-sided heterojunction photovoltaic cell manufacturing technology combined with the SmartWire or SWCT connecting technology;

the two-sided cells are two-sided heterojunction photovoltaic cells, which are arranged relative to one another so as to produce one or more strings of solar cells that are electrically connected in series and so as to allow corresponding faces of the cells to be connected via a planar interconnection without needing to use interconnects passing through the thickness of the array from one of its faces to the other;

the array of photovoltaic cells includes a plurality of protective electronic switches each comprising at least one junction forming a diode for protecting one or more photovoltaic cells, in order to protect the one or more cells from a temperature increase consecutive to defects in the uniformity of illumination of the second active faces by the reflector;

the array of two-sided photovoltaic cells is thermally decoupled from the envelope and the lifting gas that the envelope contains by a structure for holding the array of cells and for distancing it from the envelope, the distancing and holding structure being fastened to the envelope in the third zone and the array of two-sided solar cells being fastened to the distancing and holding structure, and the space bounded by the envelope, the structure and the array of cells forming an air flow channel for cooling of the two-sided solar cells by natural or forced convection;

the balloon furthermore includes one or more fans for making air flow through the channel and cool the array of photovoltaic cells;

the distancing and holding structure is deformable in order to absorb thermomechanical deformations of the envelope and/or to maintain between the envelope and the array of cells a separation that is large enough to allow the cells to be cooled;

the second zone of the envelope, which is transparent to the solar rays, partially or completely surrounds the third zone in which the first array of photovoltaic cells intended to receive the solar rays from the reflector is located, and the area of the second zone is adjusted to ensure a sufficient illumination of the photovoltaic cells of the first array and to prevent excessive heating of the solar cells and/or of the envelope and/or of the lifting gas that the envelope contains.

### BRIEF DESCRIPTION OF THE DRAWINGS

The invention will be better understood on reading the following description of a plurality of embodiments, which description is given purely by way of example and with reference to the drawings, in which:

FIG. 1 is a view of a first embodiment of a balloon according to the invention equipped with a concentrated solar generator and two arrays of single-sided solar cells, the balloon being placed in a first operating configuration in which the concentrator reflector makes a not very high solar alignment angle lower than or equal to 10 degrees;

FIG. 2 is a view of the balloon according to the invention shown in FIG. 1, the balloon being placed in a second operating configuration in which the active face of a second array of single-sided solar cells makes a high solar alignment angle strictly larger than 10 degrees and smaller than or equal to 80 degrees;

FIG. 3 is a view of a second embodiment of a balloon according to the invention equipped with a concentrated solar generator and a single array having two opposite faces of two-sided solar cells, the balloon being placed in a first operating configuration in which the concentrator reflector makes a not very high solar alignment angle smaller than or equal to 10 degrees;

FIG. 4 is a view of the balloon according to the invention shown in FIG. 3, the balloon being placed in a second operating configuration in which the second active face of the single array of two-sided solar cells makes a high solar alignment angle strictly larger than 10 degrees and smaller than or equal to 80 degrees;

FIG. 5 is a schematic view of a two-sided photovoltaic or solar cell using a heterojunction silicon technology;

FIG. 6 is a view of a two-sided solar cell such as shown in FIG. 5 using a heterojunction silicon technology combined with the SmartWire or SWCT connecting technology;

FIG. 7 is a schematic view of the planar interconnection of the solar cells of the array of two-sided solar cells in FIGS. 3 and 4 together, said interconnection forming a string of solar cells that are electrically connected in series, said array here being limited to said string;

FIG. 8 is a partial cross-sectional view of the string of solar cells in FIG. 7, through the thickness of the solar cells, this figure illustrating the arrangement of the cells and their interconnection layout;

FIG. 9 is a scale view of the array of solar cells in FIG. 7 interconnected together; and

FIG. 10 is a view of a protecting device for protecting the solar cells from abrupt variations in the illumination by concentrated rays.

### DETAILED DESCRIPTION

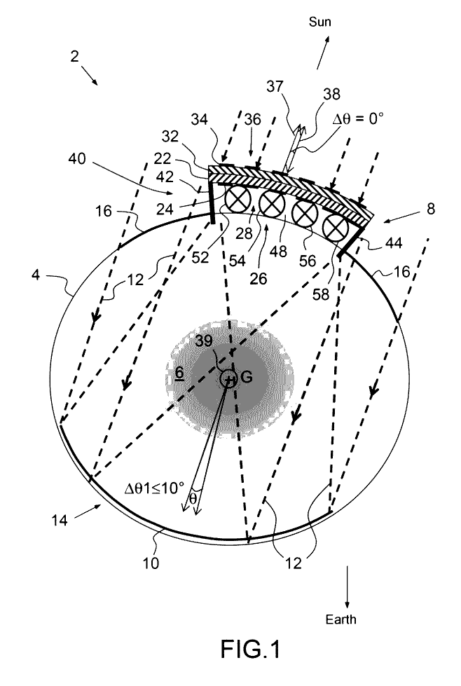

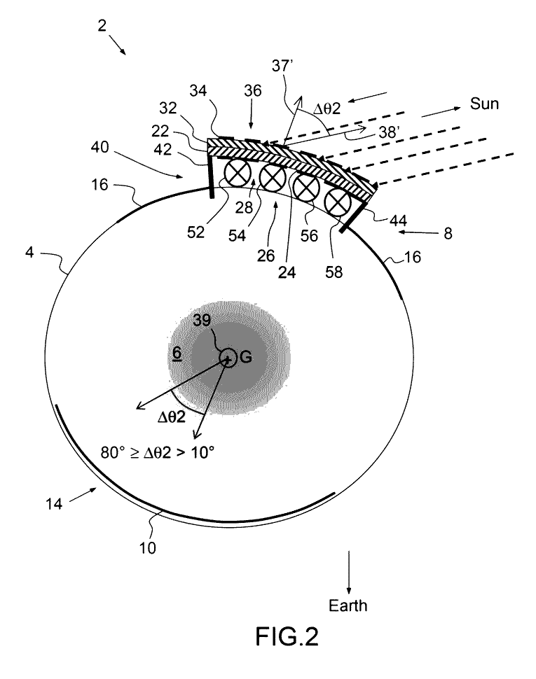

As shown in FIGS. 1 and 2 and according to a first embodiment, a balloon 2, here a high-altitude balloon, comprises a positively pressurised inflated envelope 4 filled with a lifting gas 6, for example helium, and comprises a concentrated solar radiation solar generator 8.

The solar generator 8 includes a reflector 10 of solar rays 12, which reflector is placed inside the envelope 4 in a first zone 14 of the envelope, and a second zone 16 of the envelope 4, which is transparent to the solar rays, in order to let the solar rays 12 pass to the reflector 10.

The envelope 4 is for example made of reinforced polyurethane composite. The second zone 16 of the envelope 4 may be produced by using for the envelope polyurethanes that are transparent to the solar rays and by avoiding covering the second zone 16 of the envelope with a coating that would block the passage of the solar radiation.

The solar generator 8 also includes a first array 22 of single-sided photovoltaic cells 24, which array is placed in a third zone 26 of the envelope 4, the active faces of the cells all being directed and oriented towards the reflector 10 and forming a first active face 28 of the first array 22.

The shape of the reflective surface of the reflector 10 is suitable for concentrating the solar rays on the single-sided photovoltaic cells 24 of the first array 22 and sets the angle at which the flux of the reflected beam of solar rays is concentrated on the active surface of the single-sided photovoltaic cells 24 of the first array 22.

The concentrating reflector 10 may be made from a fabric coated with a reflective coating and laminated to said polyurethane envelope in the first zone 14 of the envelope 4. The geometric concentration of the sun's rays on the photovoltaic cells 24 of the first array 22 thus makes it possible to significantly decrease the area of the first array 22 of photovoltaic cells 24 and consequently the associated weight. The concentrated solar energy thus passes through a second transparent section of the envelope, which corresponds to some or all of the third zone 26 of the envelope 4.

The solar generator 8 also includes a second array 32 of photovoltaic cells 34, which array is placed in the third zone 26 of the envelope 4 and above the first array 22. The photovoltaic active faces of the cells 34 of the second array 32 are directed and oriented towards the exterior of the envelope 4 and form a second active face 36 of the second array 32.

As a variant, the second array of single-sided photovoltaic cells is placed in a fourth zone separate from the third zone of the envelope, the photovoltaic active faces of the cells of the second array being directed and oriented towards the exterior of the envelope.

Generally, the reflector 10, the second zone 16 of the envelope, the first array 22 of single-sided photovoltaic cells 24 and the second array 32 of single-sided photovoltaic cells 34 are configured so as to ensure the first array 22 and the second array 32 of photovoltaic cells both generate electrical power provided that the rollwise solar misalignment Δθ1 of the concentrating reflector 10 is smaller than or equal to 10 degrees in absolute value, an example of this illuminating configuration being shown in FIG. 1.

As shown in FIG. 1, the rollwise solar misalignment Δθ1 of the concentrating reflector 10 is the angle made between the optical axis 37 of the reflector 10 and a current direction 38 of the sun.

As shown in FIGS. 1 and 2, the balloon is assumed to have an axis 39 of longitudinal direction 39 passing through the centre of gravity G of the balloon 2, which axis is shown from one end in FIGS. 1 and 2 and oriented forward in the latter figures, and about which the balloon 2 may be rotated by a roll angle θ.

As shown in FIGS. 1 and 2, the headingwise attitude of the balloon 2 is assumed to have been set so that the optical axis 37 of the reflector 10 and the current alignment direction of the balloon 2 towards the sun form a plane having the longitudinal direction 39 of the balloon 2 as normal.

Additionally and particularly, the concentrating reflector 10, the second zone 16 of the envelope, the first array 22 and second array 32 of single-sided solar cells are configured so as to keep the photovoltaic cells 34 of the second array 32 illuminated provided that the rollwise solar misalignment Δθ2 of the second active face 36 of the second array 32 is smaller than or equal to 80 degrees, an example of this illuminating configuration being shown in FIG. 2.

As shown in FIG. 2, the rollwise solar misalignment Δθ2 of the second active face 36 of the second array 32 is the angle made between the alignment normal 37′ of the second active face 36 of the second array 32 and a current direction of the sun 38′.

The first and second arrays 22, 32 are placed above and outside the envelope in one and the same third zone 26.

The first and second arrays 22, 32 are both superposed, the second array 32 being placed outermost from the envelope 4 and the first and second active faces 28, 36 of the first and second arrays 22, 32 being oriented in opposite directions.

This configuration promotes cooling of the photovoltaic cells 24, 34 of the first and second arrays 22, 32 since the photovoltaic cells are located and therefore heated outside of the envelope, and thus benefit from natural or forced ventilation.

The thermal decoupling of on the one hand the first and second arrays 22, 32 of photovoltaic cells and on the other hand the envelope 4 and the lifting gas 6 that the envelope 4 contains is achieved by means of a structure 40 for holding the arrays 22, 32 of solar cells 24, 34 and for distancing them from the envelope 4.

Here in FIGS. 1 and 2, two poles 42, 44 represent part of this distancing and holding structure 40. The holding structure 40 is fastened to the envelope 4 in the third zone 26 and the first and second arrays 22, 32 of single-sided photovoltaic cells 24, 34 are fastened to the holding structure 40. A space 48 bounded by the envelope 4, the structure 40 and the array of cells 24, 34 forms an air flow channel for cooling of the cells 24, 34 by forced or natural convection.

Here, in FIGS. 1 and 2, the convection is forced and ensured by four fans 52, 54, 56, 58.

Furthermore, the distancing and holding structure 40 is deformable in order to absorb thermomechanical deformations of the envelope and/or to maintain between the envelope and the array of cells a separation that is large enough to allow the cells to be cooled.

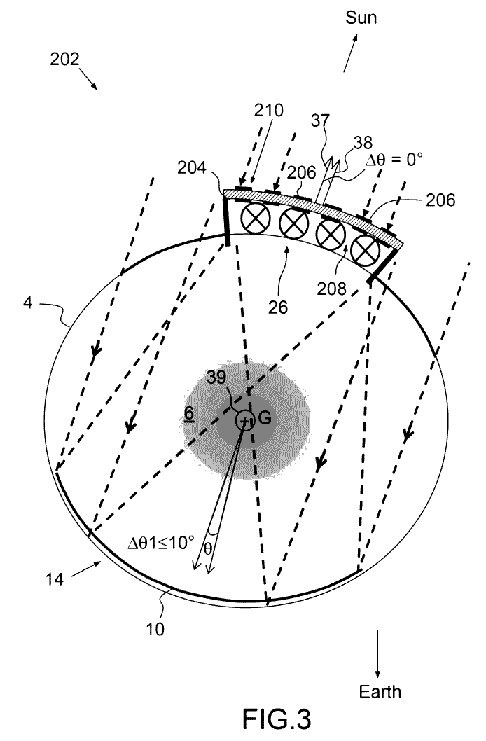

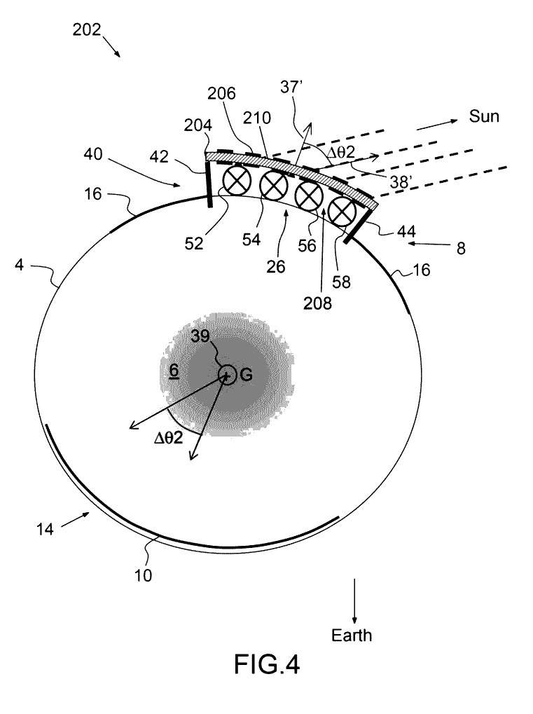

As shown in FIGS. 3 and 4 and according to a second embodiment of the balloon according to the invention, a balloon 202 equipped with a concentrated solar generator has a similar architecture to that of the balloon 2 in FIGS. 1 and 2. As regards FIGS. 3 and 4, the attitude configurations of the balloon 202 and the illumination of the balloon by the sun are the same as those in FIGS. 1 and 2, respectively.

The balloon 202 differs from the balloon 2 in that the first and second arrays 22, 32 of photovoltaic cells form one and the same single array 204 of two-sided photovoltaic cells 206, which array is located above the third zone 26 of the envelope.

The array 204 of two-sided solar cells 206 has a first active face 208, which is oriented towards the concentrator reflector 10, and a second active face 210, which is oriented towards the exterior of the envelope 4 and has an alignment direction opposite to that of the first face 208.

Generally, the concentrating reflector 10, the second zone 16 of the envelope 4, the first active face 208 and second active face 210 of the array 204 of two-sided photovoltaic cells 206 are configured so as to ensure the first and second active faces 208, 210 of the array 204 of two-sided photovoltaic cells both generate electrical power provided that the rollwise solar misalignment Δθ1 of the concentrating reflector 10 is smaller than or equal to 10 degrees in absolute value, an example of this illuminating configuration being shown in FIG. 3.

Additionally and particularly, the concentrator reflector 10, the second zone 16 of the envelope, the first active face 208 and second active face 210 of the array 204 of two-sided solar cells are configured so as to keep the second active face 210 of the array 204 illuminated provided that the rollwise solar misalignment Δθ2 of the second active face 210 of the array 204 is smaller than or equal to 80 degrees, an example of this illuminating configuration being shown in FIG. 4.

Similarly to the balloon 2 in FIGS. 1 and 2, the array 204 of two-sided solar cells 206 is thermally decoupled from the envelope 4 and lifting gas 6 that the envelope 4 contains by the distancing and holding structure 40. The decoupling of the solar cells from the envelope of the balloon allows the two-sided solar cells to be cooled by natural or forced convection, thereby improving the efficiency of the solar cells as the latter are more efficient at low temperatures.

As shown in FIGS. 3 and 4, the convection is here forced and ensured by the four fans 52, 54, 56, 58.

Furthermore, the distancing and holding structure 40 is deformable in order to absorb thermomechanical deformations of the envelope 4 and/or to maintain between the envelope 4 and the array 204 of two-sided solar cells 206 a separation that is large enough to allow the cells to be cooled.

The technology used to manufacture the two-sided cells 206 is a technology chosen from the group consisting of the PERT (passivated emitter rear totally diffused) silicon technology, the silicon heterojunction (HTJ) technology and the IBC (interdigitated back contact) silicon technology.

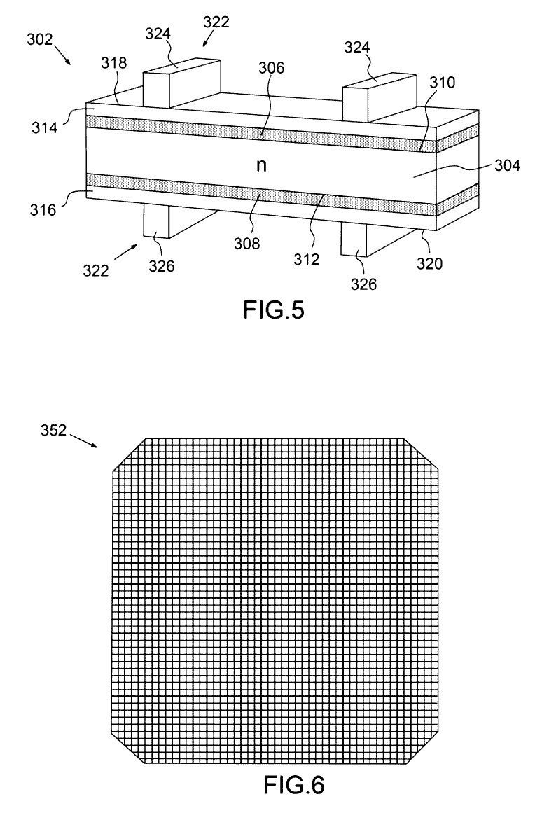

As shown in FIG. 5 and according to a conventional two-sided solar cell structure using a heterojunction silicon technology, a two-sided photovoltaic or solar cell 302 includes a set of superposed layers.

The solar cell 302 includes a central layer 304 forming a high-quality n-type single-crystal silicon substrate on a first face 310 and a second face 312 of which amorphous silicon layers 306, 308 of nanoscale thickness are deposited to create a junction and thus ensure an excellent surface passivation. Transparent oxide layers 314, 316, which ensure the lateral conduction of charge and allow optical confinement to be improved, are deposited on the amorphous silicon layers 306, 308. A metal compound 322 forming a first set of grid finger electrodes 324 and a second set of grid finger electrodes 326, respectively, is deposited on the faces 318, 320 in order to ensure effective collection of the generated charges.

Thus, this symmetric structure of the solar cell 302 allows both faces or sides to be electrically active under illumination.

Preferably, the technology used to manufacture and connect the two-sided cells is a two-sided heterojunction photovoltaic cell manufacturing technology combined with the SmartWire or SWCT connecting technology.

In the SWCT process, metal wires are embedded in a polymer sheet that is applied directly to the metallised surface of the solar cell. Next, the assembly formed by the solar cell and the polymer sheet inlaid with the metallised wires is laminated. The metal wires are thus fastened to the metal layer of the cell and form an electrical contact.

Increasing the number of busbars running across each of the faces of the two-sided solar cell and decreasing the thickness of said busbars allows a better compromise to be obtained between decrease of ohmic losses in the grid finger electrodes and decrease of shadowing of the surface of the solar cell.

The use of the SmartWire or SWCT connecting technology is the ultimate result of this evolution, the metallisation being distributed over the entire surface of the solar cell as illustrated by a typical cell 352 in FIG. 6.

Advantageously, the use of the SWCT technology, which is compatible with a silicon heterojunction HTJ technology, decreases the resistance and shadowing of the solar cell, distributes mechanical stresses over the entire surface of the cell, and increases the resistance of the connections to thermal cycling relative to a technology using busbars.

Preferably, solar cells of the same type as the solar cell 352 are interconnected together via corresponding active faces of the assembly, thereby avoiding the need for connections to be passed between the face of a first cell, which face is located on the same side as the first face of the array, and the face of a second cell adjacent to the first cell, which face is located on the same side as the second face of the array.

The process called the planar process for interconnecting two-sided heterojunction solar cells comprises a first step and a second step.

In the first step, the two-sided heterojunction cells of a given string of cells that are intended to be electrically connected in series are arranged relative to one another so as to achieve, on the first active face of the array, a first alternated distribution of a first and second polarity, each two-sided cell having a first face associated with the first polarity and a second face having a second polarity. Complementarily in terms of polarities, the same string of solar cells has a second alternated distribution of the second polarity and first polarity on the second active face of the array.

Next, in the second step, for each face of the array of two-sided cells and depending on the arrangement of the cells that are intended to form one or more strings, corresponding faces of the cells are connected together via a planar interconnection without needing to use interconnects passing through the thickness of the array from one of its active faces to the other.

Planar interconnects decrease the risk of damage during thermal cycles and simplify the process for manufacturing the array of two-sided solar cells.

Advantageously, the planar interconnecting process and the process for implementing the SWCT technology may be combined by carrying out the laminating step of the SWCT technology and the actual interconnecting second step of the interconnecting process at the same time in a shared baking phase.

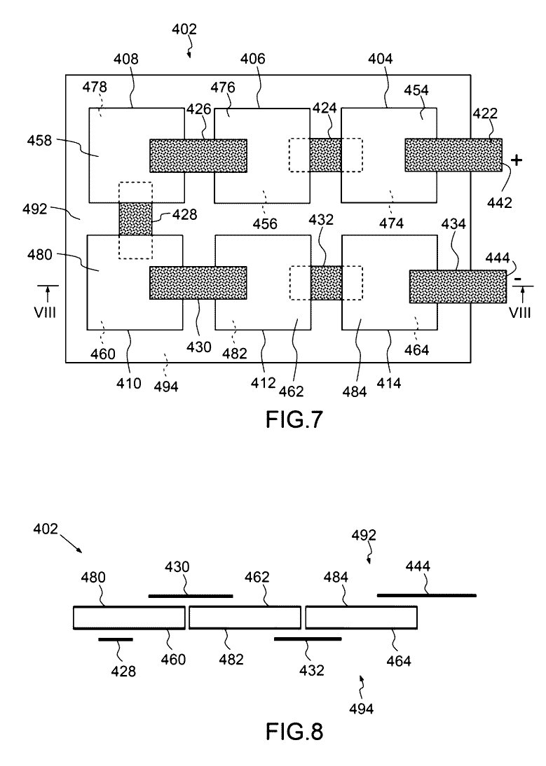

As shown in FIG. 7 and according to an exemplary cell interconnection layout, an array 402 of two-sided solar cells comprises a number of two-sided solar cells, here six solar cells 404, 406, 408, 410, 412, 414, that are connected together by metal ribbons 422, 424, 426, 428, 430, 432, 434 to form here a string of photovoltaic cells that are electrically connected in series between a first electrical terminal 442 at a first polarity, here positive, and a second electrical terminal 444 at a second polarity, here negative.

Each two-sided solar cell 404, 406, 408, 410, 412, 414 respectively includes a first face 454, 456, 458, 460, 462, 464 at the first polarity and a second face 474, 476, 478, 480, 482, 484 at the second polarity.

The ribbons 422, 424, 426, 428, 430, 432, 434 respectively connect the first electrical terminal 442, the second face 474, the second face 476, the second face 478, the second face 480, the second face 482 and the second face 484 to the first face 454, the first face 456, the first face 458, the first face 460, the first face 462, the first face 464 and the second electrical terminal 444.

Thus, the electromotive force generated by placing the solar cells in series between the first electrical terminal and the second electrical terminal is equal to the sum of the electromotive forces of the solar cells 404, 406, 408, 410, 412 and 414.

The array 402 of solar cells forms a panel or module of solar cells having radii of curvature that are clearly larger than the size of one solar cell, the panel or module having a first face 492 intended to be oriented towards the exterior of the balloon and illuminated directly by the sun, and a second face 494 intended to be oriented towards the interior of the balloon and illuminated by the concentrating reflector.

In FIG. 8 the interconnection layout of solar cells 410, 412 and 414 forming part of the single string of the array 402 in FIG. 7 is shown and illustrated by a partial cross section of the array 402.

The absence of interconnects between cells passing through the thickness of the array from one active face to the other, may be clearly seen in FIG. 8.

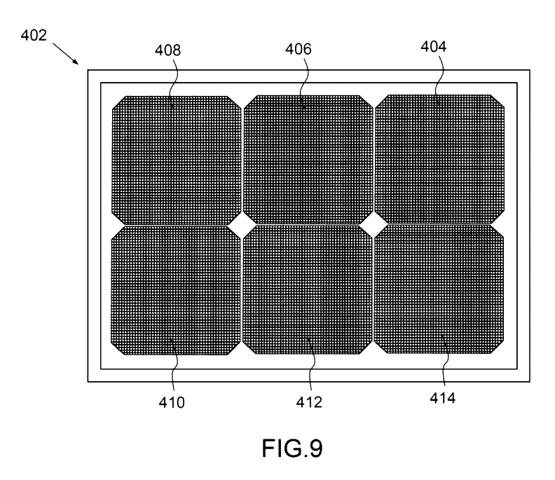

FIG. 9 is a scale view from above showing the array 402 of solar cells 404, 406, 408, 410, 412, 414 interconnected together according to the interconnection layout illustrated in FIGS. 7 and 8.

It will be noted that generally, the array of two-sided solar cells is not limited to a single string of solar cells.

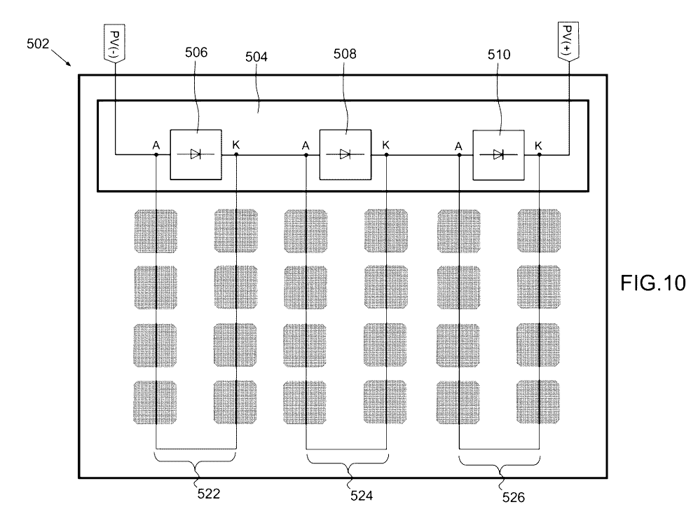

As shown in FIG. 10 and according to one example of an array of two-sided solar cells, an array 502 of photovoltaic cells includes a plurality 504 of protective electronic switches 506, 508, 510 each comprising at least one junction forming a diode.

The plurality 504 of protective electronic switches 506, 508, 510 is configured to protect one or more photovoltaic cells 522, 524, 526 from a temperature increase consecutive to defects in the uniformity of illumination of the first active face of the array 502 by the concentrator reflector.

The electronic switches are for example discreet diodes or transistors or associations of diodes and/or transistors.

It will be noted that in addition to the moderating effect that the use of a second array of single-sided solar cells or a second active face of a single array of two-sided solar cells has, via its contribution to the delivery of a given electrical power at a nominal reference alignment, on the heating of the array, provision may be made, in one variant of the embodiments described above, for a second skin for protecting the envelope, in so far as it receives a concentrated beam of solar rays. Particular polyurethane films may be used for this purpose.

Whatever the variant used, the reflective zone of the second zone of the envelope may have the shape of the envelope: in this case, the shape of the envelope is chosen to optimise both the lift of the balloon and the optical convergence of the solar rays towards the photovoltaic cells.

According to one variant of the invention, the envelope may comprise a first skin and a second skin comprising the reflective zone of the reflector, in order for it to be able to have a different shape to that of the envelope. In this case, the shape of the envelope and that of the reflective surface of the reflector may be chosen independently. The shape of the envelope may be adapted to optimise lift, the shape of the reflective surface being chosen solely for optical reasons. In this case and advantageously, the reflective zone may be deformable so as to optimise its shape to also take account of the angle of incidence of the solar rays. This angle may vary depending on the time of day, the season, the altitude and the geographical position of the balloon.

Generally, the shape of the envelope is preferably axisymmetric. An ellipsoidal envelope shape is suitable for ensuring a satisfactory lift and optical performance, in particular if the reflective surface is the same as that of the envelope. Alternatively, the envelope may be of parabolic shape.

Conventional balloon shapes, which may equally well be spherical as parabolic, may be used, in particular if the shape of the reflective zone is independent of the shape of the envelope.

The reflective zone is preferably parabolic in shape.

Generally, the configuration of the envelope confers on the reflective zone that forms part thereof a power of concentration of solar rays in the direction of the photovoltaic cells. The concentration factor may be adjustable, typically it may be higher than 1 and lower than 5, and vary with the time of day since the angle θ of the solar rays varies with time of day.

Generally, in all the embodiments of the balloon according to the invention, the solar cells, when they are in nominal alignment, are illuminated by concentration from the interior of the balloon, and from the exterior of the balloon by direct radiation from the sun, thereby allowing, at given generated electrical power and relative to a solution using a concentrator alone, the radiant power of the concentrator, which is a potential source of a risk of damage to the balloon because of possible heating of the envelope and/or of the lifting gas contained in the envelope, to be limited.

In case of sufficient rollwise misalignment, i.e. of about 10 degrees, the solar cells configured to receive radiation from the concentrator will no longer be illuminated from the interior of the balloon but those oriented towards the exterior of the balloon will still be illuminated directly by the sun provided that the rollwise misalignment of the balloon remains below 80 degrees, thereby making it possible to limit the use of the on-board power storage system, which is for example a fuel-cell stack. Furthermore, this system is more robust to any yaw-wise misalignment, i.e. to changes in heading.

The advantage of this solution is that, in case of misalignment, even if the concentration is not operational the face oriented directly towards the sun will still be operational, especially during balloon transition and/or manoeuvre phases.

To obtain equivalent results and an equivalent performance, the two-sided cells may be replaced by a pair of single-sided solar cells, or indeed the two functions of the solar generator, with internal concentration and without external concentration, may be disassociated and placed in different locations.

These solutions are suboptimal relative to the solution using two-sided cells because in these cases the total number of solar cells forming the two arrays is practically doubled, thereby leading to a greater weight and an increase in complexity.

Generally, the high-altitude balloon described above may be replaced by any other type of balloon intended to cruise in other layers of the atmosphere provided that the features of the invention remain the same.

1. A balloon equipped with a concentrated solar generator comprising an envelope containing a lifting gas and a concentrated solar radiation solar generator,
the solar generator including
a reflector of solar rays, which reflector is placed inside the envelope in a first zone of the envelope,
a second zone of the envelope, which is transparent to the solar rays, in order to let the solar rays pass to the reflector, and
a first array of photovoltaic cells, which array is placed in a third zone of the envelope, having a first active face directed towards the reflector;
the first array of photovoltaic cells and the reflector being configured so that the reflector concentrates the solar rays on the first active face of the first array of photovoltaic cells when the reflector is placed in a solar alignment position;
wherein
the solar generator further includes a second array of photovoltaic cells, which array is placed in a fourth zone of the envelope or in the third zone of the envelope, and having a second active face directed towards the exterior of the envelope; or
the solar generator includes a single first array the solar cells of which are two-sided solar cells and the first array includes a second active face directed towards the exterior of the envelope; and
the reflector, the single first array of two-sided photovoltaic cells or the first and second arrays of photovoltaic cells are configured so as to ensure the first active face and the second active face both generate electrical power provided that the rollwise solar misalignment of the reflector is smaller than or equal to 10 degrees in absolute value.

2. The balloon equipped with a concentrated solar generator according to claim 1, wherein the reflector, the single first array of two-sided photovoltaic cells or the first and second arrays of photovoltaic cells are configured so as to keep the second active face illuminated provided that the rollwise solar misalignment of the second active face is smaller than or equal to 80 degrees.

3. The balloon equipped with a concentrated solar generator according to claim 1, wherein
the first and second arrays of photovoltaic cells are separate and placed in different third and fourth zones, respectively.

4. The balloon equipped with a concentrated solar generator according to claim 1, wherein
the first and second arrays of photovoltaic cells are separate and each include single-sided photovoltaic cells; and
the first and second arrays are placed on and outside of the envelope in the same zone;
the first and second arrays are mutually superposed, the second array being placed outermost from the envelope and the active faces of the photovoltaic cells of the first and second arrays being oriented in opposite directions.

5. The balloon equipped with a concentrated solar generator according to claim 1, wherein the first array and the second array are mechanically decoupled from the envelope in terms of deformations of the envelope and/or thermally from the envelope and from the lifting gas that the envelope contains.

6. The balloon equipped with a concentrated solar generator according to claim 1, wherein
the first array of photovoltaic cells is an array of two-sided photovoltaic cells, which array is located above the third zone of the envelope,
each two-sided cell having a first face associated with a first electrical bias and a second face associated with a second electrical bias.

7. The balloon equipped with a concentrated solar generator according to claim 6, wherein the technology used to manufacture the two-sided cells is a technology chosen from the group consisting of the PERT (passivated emitter rear totally diffused) silicon technology, the silicon heterojunction (HTJ) technology and the IBC (interdigitated back contact) silicon technology.

8. The balloon equipped with a concentrated solar generator according to claim 7, wherein the technology used to manufacture and connect the two-sided cells is a two-sided heterojunction photovoltaic cell manufacturing technology combined with the SmartWire or SWCT connecting technology.

9. The balloon equipped with a concentrated solar generator according to claim 7, wherein the two-sided cells are two-sided heterojunction photovoltaic cells,
which are arranged relative to one another so as to produce one or more strings of solar cells that are electrically connected in series and so as to allow corresponding faces of the cells to be connected together via a planar interconnection without needing to use interconnects passing through the thickness of the array from one of its faces to the other.

10. The balloon equipped with a concentrated solar generator according to claim 6, wherein the array of photovoltaic cells includes a plurality of protective electronic switches each comprising at least one junction forming a diode for protecting one or more photovoltaic cells, in order to protect the one or more cells from a temperature increase consecutive to defects in the uniformity of illumination of the second active faces by the reflector.

11. The balloon equipped with a concentrated solar generator according to claim 6, wherein
the array of two-sided photovoltaic cells is thermally decoupled from the envelope and the lifting gas that the envelope contains by a structure for holding the array of cells and for distancing it from the envelope,
the distancing and holding structure being fastened to the envelope in the third zone and the array of two-sided solar cells being fastened to the distancing and holding structure,
and the space bounded by the envelope, the structure and the array of cells forming an air flow channel for cooling of the two-sided solar cells by natural or forced convection.

12. The balloon equipped with a concentrated solar generator according to claim 11, including one or more fans for making air flow through the channel and cool the array of photovoltaic cells.

13. The balloon equipped with a concentrated solar generator according to claim 11, wherein the distancing and holding structure is deformable in order to absorb thermomechanical deformations of the envelope and/or to maintain between the envelope and the array of cells a separation that is large enough to allow the cells to be cooled.

14. The balloon equipped with a concentrated solar generator according to claim 1, wherein
the second zone of the envelope, which is transparent to the solar rays, partially or completely surrounds the third zone in which the first array of photovoltaic cells intended to receive the solar rays from the reflector is located, and
the area of the second zone is adjusted to ensure a sufficient illumination of the photovoltaic cells of the first array and to prevent excessive heating of the solar cells and/or of the envelope and/or of the lifting gas that the envelope contains.
